(19) United States
(12) Patent Application Publication
(10) Pub. No.: US 2011/0297206 A1
(43) Pub. Date: Dec. 8, 2011

(54) CONCENTRATED SOLAR POWER RECEIVER MAINTENANCE SYSTEM

(76) Inventor: Timothy Devine, Ojai, CA (US)

(21) Appl. No.: 12/796,648

(22) Filed: Jun. 8, 2010

(51) Int. Cl. H01L 31/052; B66C 25/00; B23P 19/00

(52) U.S. Cl. 136/246; 29/426.3; 29/823; 414/373

(57) ABSTRACT

A solar receiver system that includes an integral replacement system.

### BACKGROUND

The present disclosure relates to a concentrated solar power tower system, and more particularly to a maintenance system therefor.

Heliostats are minor structures that direct the sun's energy to a solar receiver to produce electric power. The heliostat and solar receiver are often referred to as a concentrated solar power tower system.

The solar receiver includes a multiple of concentrated solar power (CSP) receiver panels which may be approximately 63×12×7 feet (19×4×2 meters) in dimension and weigh upwards of 36,000 pounds (16,300 Kilograms) each. To provide maintenance of a single CSP receiver panel, the particular CSP receiver panel must be precisely controlled in all directions at all times to avoid contact with adjacent CSP receiver panels. Such control must also accommodate wind effects as wind is typically a significant factor at the altitudes at which the solar receiver is mounted.

### BRIEF DESCRIPTION OF THE DRAWINGS

Various features will become apparent to those skilled in the art from the following detailed description of the disclosed non-limiting embodiment. The drawings that accompany the detailed description can be briefly described as follows:

FIG. 1 is a general schematic view of a solar power tower system with an integral maintenance system;

FIGS. 2-9 are example illustrations of the integral maintenance system operation;

FIG. 10 is an expanded view of a track system for the cart system; and

FIG. 11 is a flowchart illustration operation of the integral maintenance system.

### DETAILED DESCRIPTION

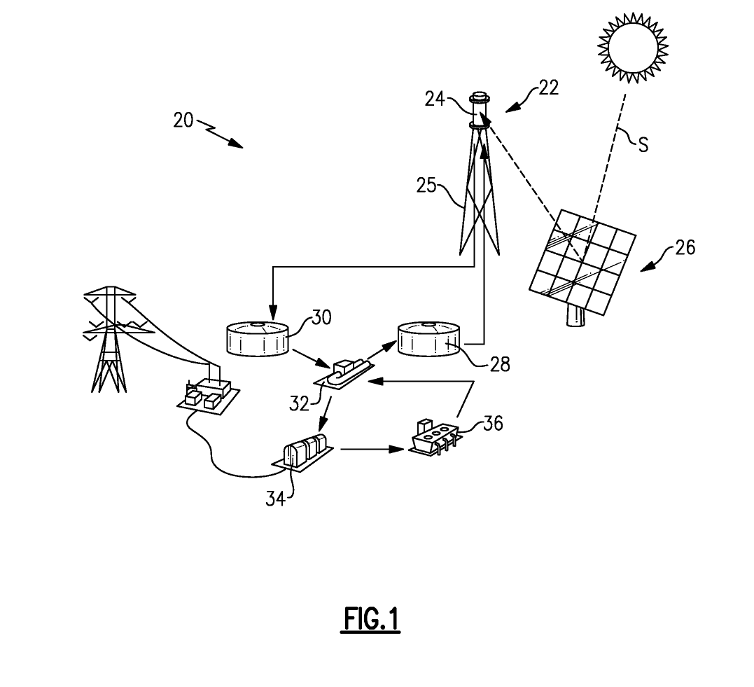

Referring to FIG. 1, a solar power tower system 20 includes a high concentration central solar receiver system 22 having a concentrated solar power (CSP) receiver panel array 24 mounted to a tower structure 25 at a predetermined height, typically hundreds of feet, above ground to receive reflected solar radiation S. The tower structure 25 may be manufactured in various manners. A multiple of sun-tracking mirrors or heliostats 26 reflect and focus solar radiation S onto the concentrated solar power (CSP) receiver panel array 24.

Molten salt or other thermal transfer fluid is communicated from a cold storage tank system 28 through the solar receiver system 22 where the fluid is heated by the reflected solar radiation. The heated thermal transfer fluid is then communicated to a hot storage tank system 30. When power is required, the hot thermal transfer fluid is pumped to a steam generator system 32 that produces steam. The steam drives a steam turbine/generator system 34 that creates electricity for communication to a power grid. From the steam generator system, the cooled steam is passed through a condenser system 36. The thermal transfer fluid, (salt) that supplied heat to the steam generation system 32 will be cooled after steam generation and will be pumped to the cold storage tank 28 where it is stored and eventually reheated in the solar receiver and routed to the hot storage tank 30.

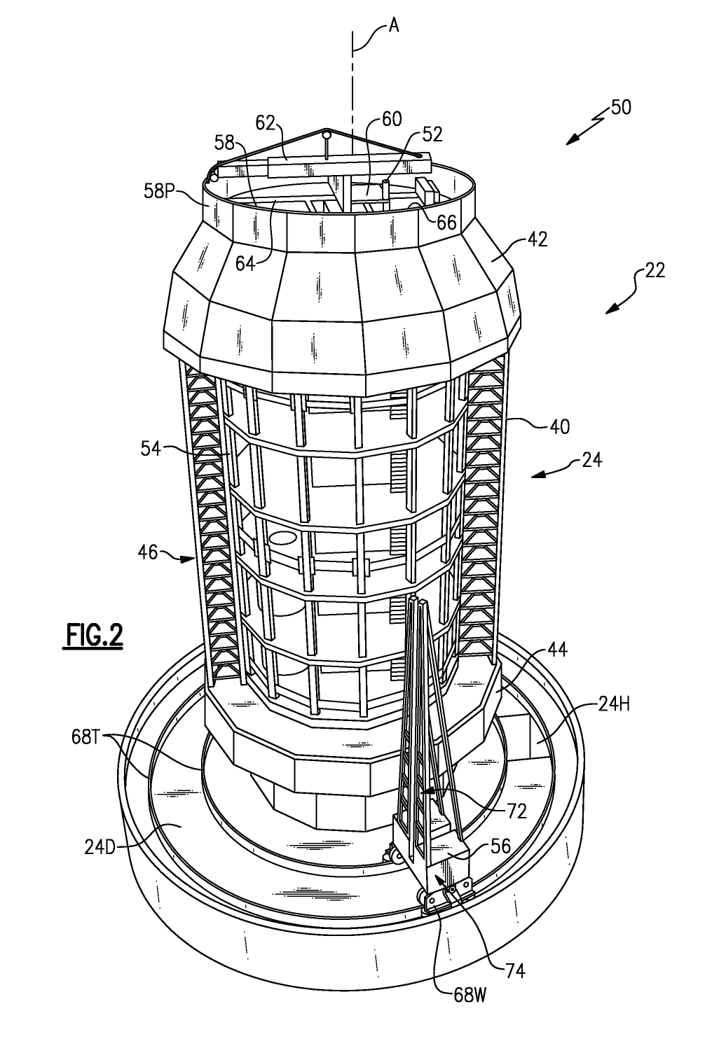

Referring to FIG. 2, the concentrated solar power (CSP) receiver panel array 24 generally includes a multiple of concentrated solar power (CSP) receiver panels 40 between a multiple of upper cover assemblies 42 and a multiple of lower cover assemblies 44. In one non-limiting embodiment, the concentrated solar power (CSP) receiver panel array 24 utilizes 14 CSP receiver panels 40. It should be understood that various cover assemblies may alternatively or additionally be provided.

Each of the CSP receiver panels 40, in one non-limiting embodiment, are 63 feet by 12 feet by 7 feet in volume and weigh approximately 36,000 pounds. To provide for the repair or replacement of a CSP receiver panel 40, the CSP receiver panel 40 must be precisely controlled as the multiple of CSP receiver panels 40 are disposed in close proximity to each other when mounted. Moreover, the tower structure 25 is hundreds of feet tall such that wind may be a significant factor during the repair or replacement of the CSP receiver panel 40.

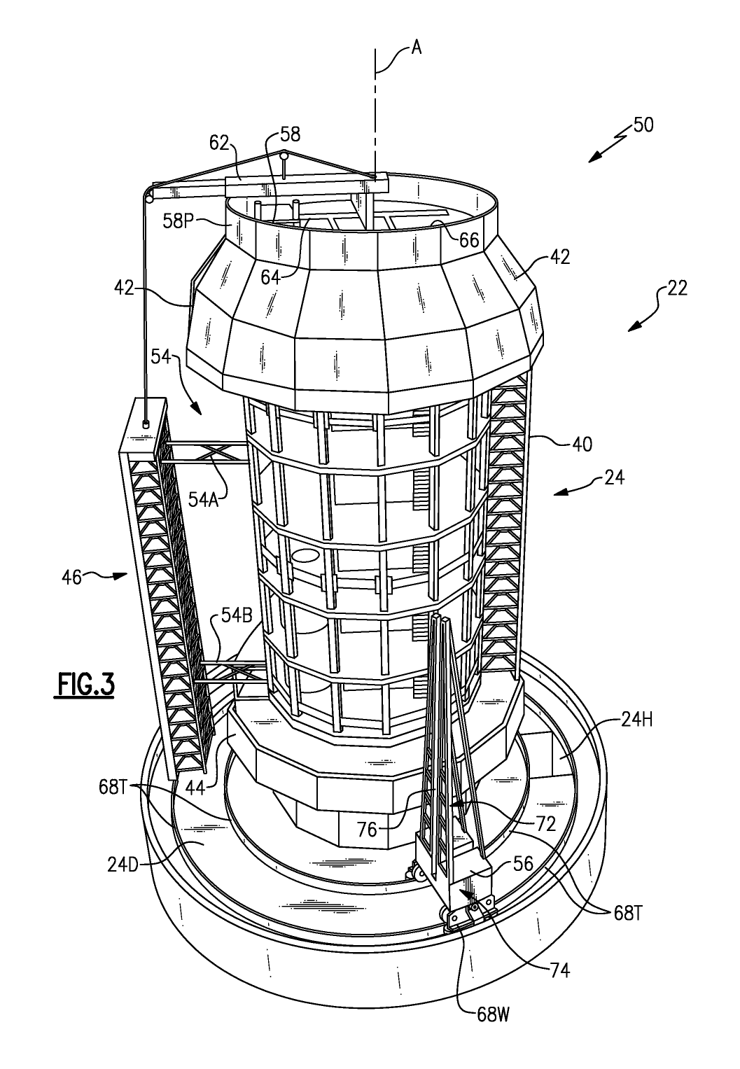

The solar receiver system 22 includes an integral maintenance system 50. The maintenance system 50 generally includes a crane system 52, a linkage 54 (FIG. 3), and a cart system 56. The maintenance system 50 facilitates the repair and/or replacement of any CSP receiver panel 40 from the solar receiver system 22 without the heretofore necessity of external equipment.

The crane system 52 may be mounted atop the solar receiver system 22 upon a roof 58 thereof. The crane 52 system generally includes a crane body 60, a crane arm 62, and a track system 64. The crane body 60 may be movable between a central position along an axis A of the roof 58 and an outer perimeter 58P of the roof 58. The crane body 60 also pivots about axis A upon a turntable 66 such that the crane arm 62 has access to every CSP receiver panel 40 mounted about the concentrated solar power (CSP) receiver panel array 24. It should be understood that various crane arrangements may alternatively be provided.

The linkage 54 may be removably mounted to any CSP receiver panel 40 to selectively permit the CSP receiver panel 40 to move directly away from the concentrated solar power (CSP) receiver panel array 24 without interference or contact with the directly adjacent CSP receiver panels 40. That is, the linkage 54 includes an upper linkage 54A and a lower linkage 54B about which the CSP receiver panel 40 pivots outwardly relative to axis A as well as at least partially along axis A relative to a receiver deck 24D defined about the solar receiver system 22 (FIG. 3).

A track 68T is defined around the receiver deck 24D upon which the cart system 56 is guided. It should be understood that although a pair of tracks are illustrated in the disclosed non-limiting embodiment, other track arrangements such as a single track may alternatively be provided. The track 68T guides the carts 56 around the receiver deck 24D at a radial distance which corresponds to the radial extension of the linkage assembly 54 (FIG. 3). That is, the linkage assembly 54 displaces the CSP receiver panel 40 to be at a predetermined position relative to the track 68T such that a frame assembly 72 mounted to each cart 74 of the cart system 56 is engageable with the CSP receiver panel 40. The frame assembly 72 may be an A-frame arrangement that includes an engagement system 76 operable to selectively receive the CSP receiver panel 40. Each cart assembly 74 engages one side of the CSP receiver panel 40 and may additionally engage the opposite cart to form a single rigid unit which may support the weight of the CSP receiver panel 40 for secure movement along track 68T.

The frames 72 are of a significant height so as to control the movement of the CSP receiver panel 40 when moved by the crane system 52. That is, the CSP receiver panel 40 free hang time from the crane system 52 and the linkage system 54 is minimized or completely eliminated.

An access hatch 24H is located through the receiver deck 24D. The access hatch 24H may be located within track 68T and sized to permit passage of the CSP receiver panel 40.

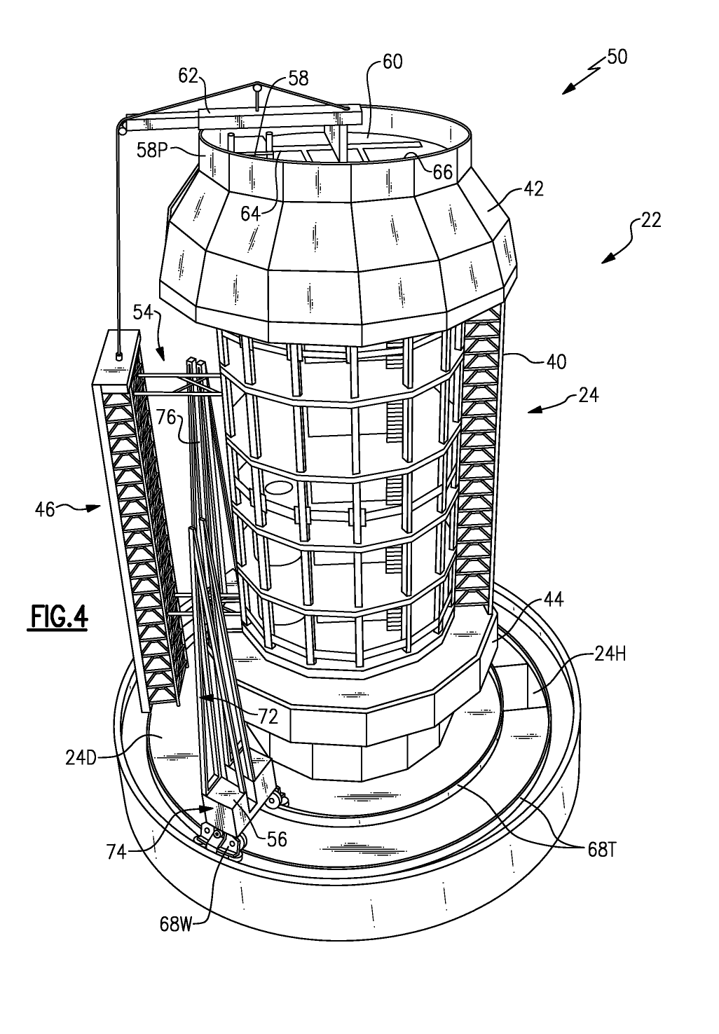

In operation, the crane system 52 is rotated to an azimuthal position associated with the CSP receiver panel 40 which is to be removed from the concentrated solar power (CSP) receiver panel array 24 (FIG. 4). The crane arm 62 is positioned such that a cable therefrom is operably attached to the CSP receiver panel 40 once the cover assemblies 42, 44 are removed by the crane.

The linkage 54 may be temporarily attached between the CSP receiver panel 40 which is to be removed and a support structure of the solar receiver system 22. The linkage assembly 54 may alternatively be mounted to every CSP receiver panel 40 such that temporary installation is avoided. However, considering the infrequency of CSP receiver panel repair or replacement, a temporary installation of the linkage assembly 54 avoids duplication and weight upon each CSP receiver panel 40.

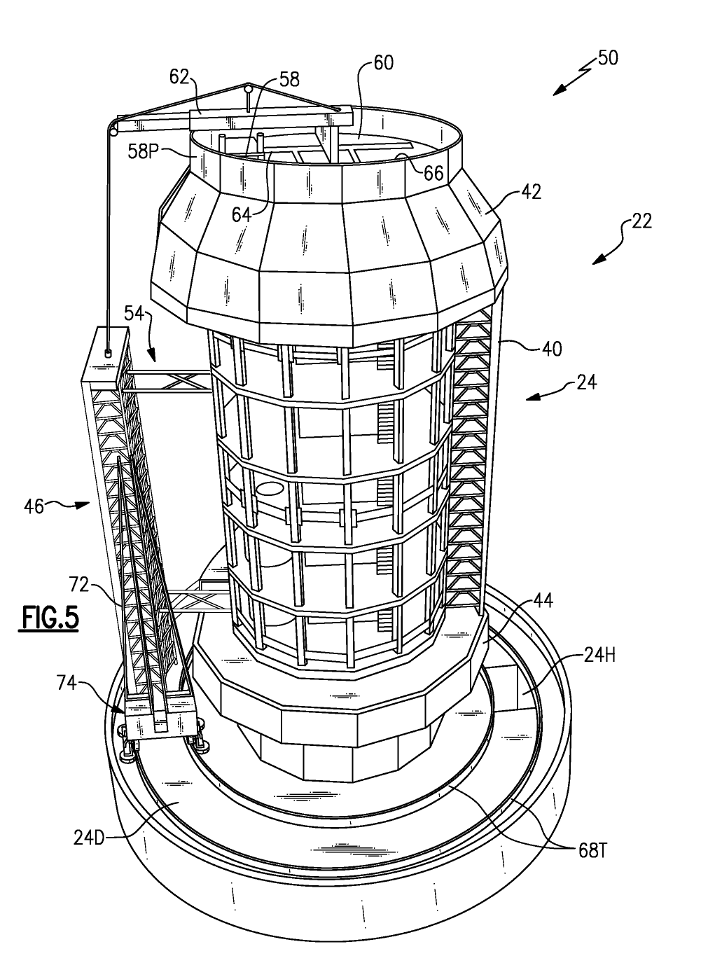

Once the linkage assembly 54 and the cable from the crane system 52 are attached to the desired CSP receiver panel 40, attachments between the CSP receiver panel 40 and the solar receiver system structure 22 may be released. The crane arm 62 will thereby deploy cable such that the CSP receiver panel 40 is lowered from an installed position to a lowered position under the complete control of the linkage assembly 54 (FIGS. 4 and 5). The crane system 52 thus supports the weight of the CSP receiver panel 40 while the linkage assembly 54 guides movement of the CSP receiver panel 40. The linkage assembly 54 thus need not be powered as the motive force is provided by gravity and limited or controlled solely by the crane system 52.

Once the CSP receiver panel 40 is moved to a lowered position by the crane system 52, the cart system 56 is deployed to both sides of the CSP receiver panel 40 (FIG. 5). The CSP receiver panel 40 is then attached to each frame 72 of the respective cart 74. The cart system 56 thereafter controls the position of the CSP receiver panel 40 which may at least partially or completely support the weight of the CSP receiver panel 40.

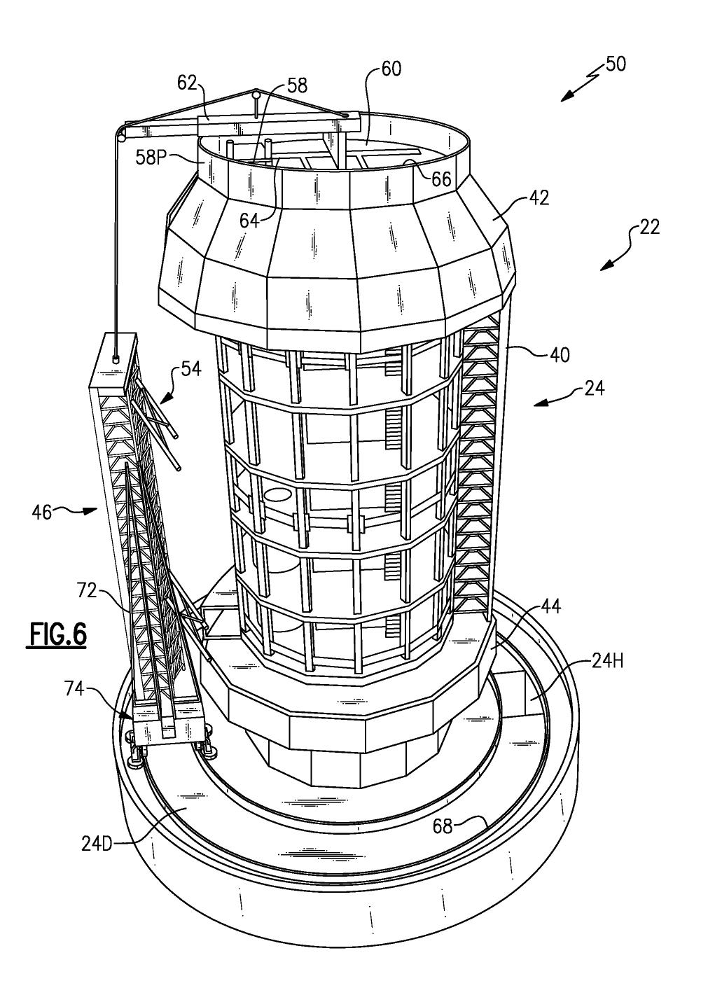

The cart system 56 is powered to drive or otherwise be propelled, pushed or pulled along track 68T. That is, the crane system 52 may remain attached to the CSP receiver panel 40, but the movement of the CSP receiver panel 40 is through the self-powered cart system 56 around the receiver deck 24D. It should be understood that various systems may be utilize to provide the motive force, for example, separate carts, tugs or other internally powered carts around the receiver deck 24D. Once restrained by the cart system 56, the linkage assembly 54 is detached from the solar receiver system 22. The linkage assembly 54 may then be stowed on the CSP receiver panel 40 (FIG. 6).

The cart system 56 may be powered electrically or otherwise. Provisions for the cart system 56 to be powered permit the crane system 52 to solely support the CSP receiver panel 40 weight and not be required to pull or lead the CSP receiver panel 40 around the receiver deck 24D. That is, the crane system 52 supports the CSP receiver panel 40 weight, while the crane system 52 and the cart system 56 are rotated around the receiver deck 24D in unison. Moreover, the CSP receiver panel 40 is again under precise control which minimizes wind effects that almost always exist atop the tower structure 25.

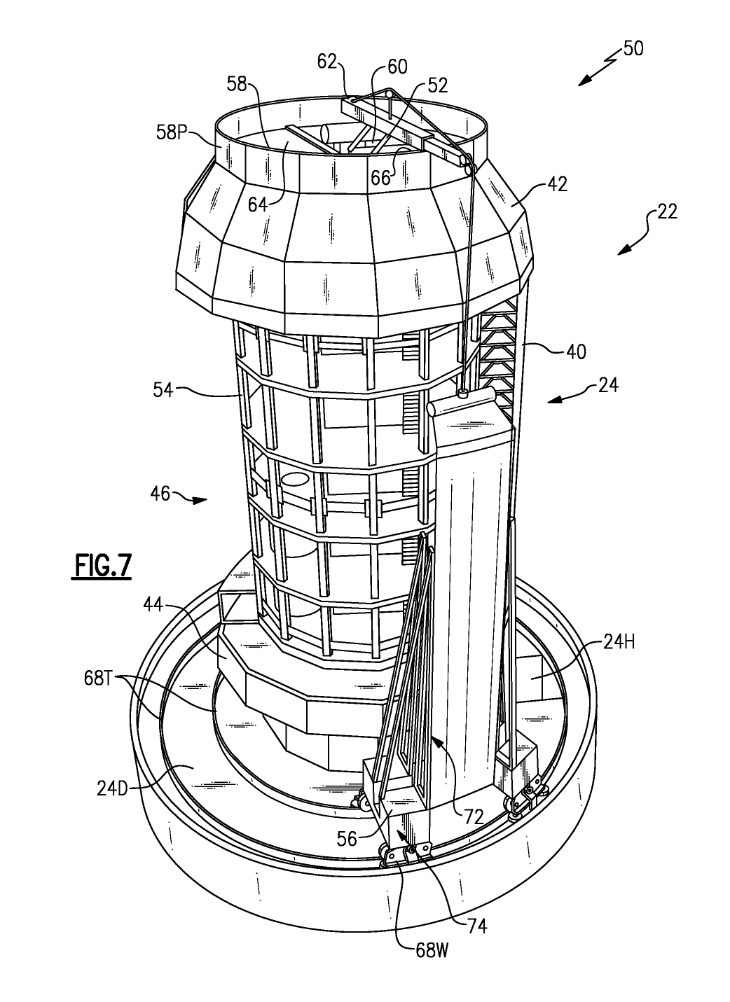

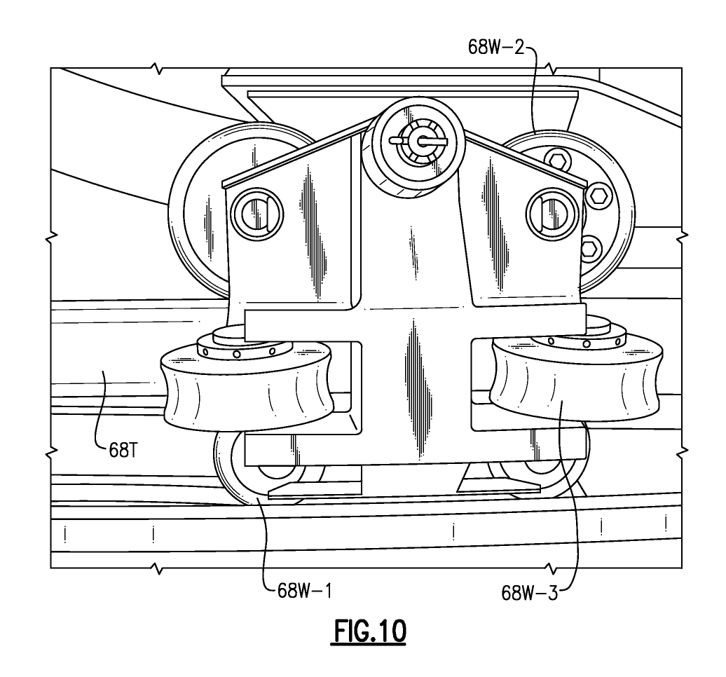

The cart system 56 travels along a track 68T until the CSP receiver panel 40 is above the access hatch 24H (FIG. 7). The wheels 68W for the cart system 56 may capture the track 68T to resist any wind forces and provide a rigid support for the CSP receiver panel 40. For example only, one set of wheels 68W−1 will be in tension while another set of wheels 68W−2 may be in compression (FIG. 10). That is, the wheels on opposite sets may be in alternating compression and tension. For example, if wheels 68W−1 of the outboard set of wheels are in tension, then wheels 68W−2 of the inboard set of wheels will be in compression. A pre-load may be set in the wheels such that they are all loaded initially (and that is what is described here) but the point is for the wheels to retain the cart system 56 and CSP receiver panel 40 to prevent a rolling moment that will be generated by the wind, i.e., inside wheels in compression, outside wheels in tension (or the opposite).

The track 68T may, alternatively or in addition, be captured by the wheels 68W−1, 68W−2 with other wheel sets 68W−3 to provide lateral restraint. The wheels 68W and track 68T assure that no forces are transferred to the CSP receiver panel 40 which may otherwise damage the CSP receiver panel 40. It should be understood that various arrangements may alternatively or additionally benefit herefrom to provide the desired rigid constraint and safe control of the CSP receiver panel 40.

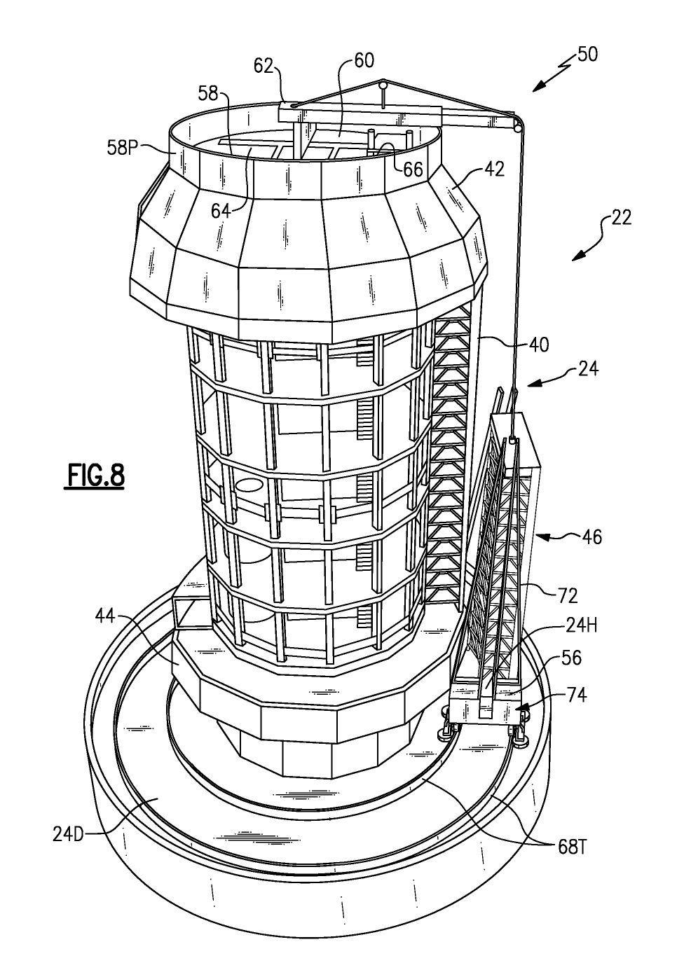

Once properly positioned over the access hatch 24H (FIG. 8), the crane system 52 again supports the weight of the CSP receiver panel 40 as the CSP receiver panel 40 is detached from the assemblies 72 of the cart system 56. It should be understood that various track and guide systems may be provided by the frame assemblies to provide controlled movement of the CSP receiver panel 40.

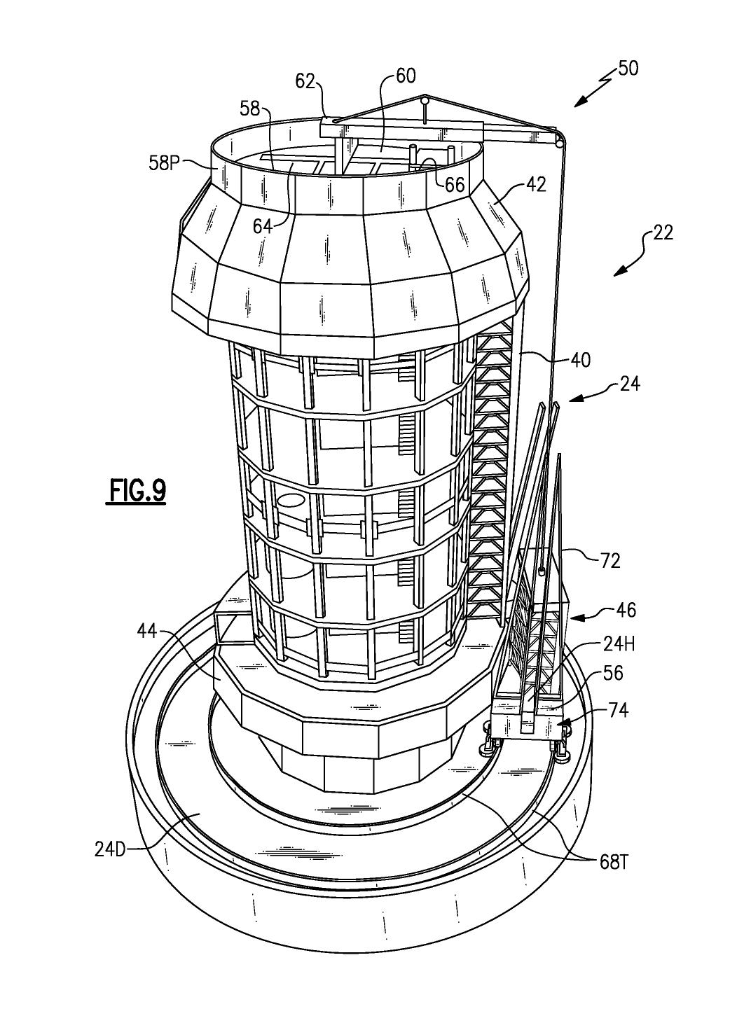

The CSP receiver panel 40 is lowered through the access hatch 24H to another level (not shown) typically less than 300 feet below the receiver deck 24D (FIG. 9). Once lowered, the CSP receiver panel 40 may be transferred to an elevator system or other system (not shown) to lower the CSP receiver panel 40 to the ground.

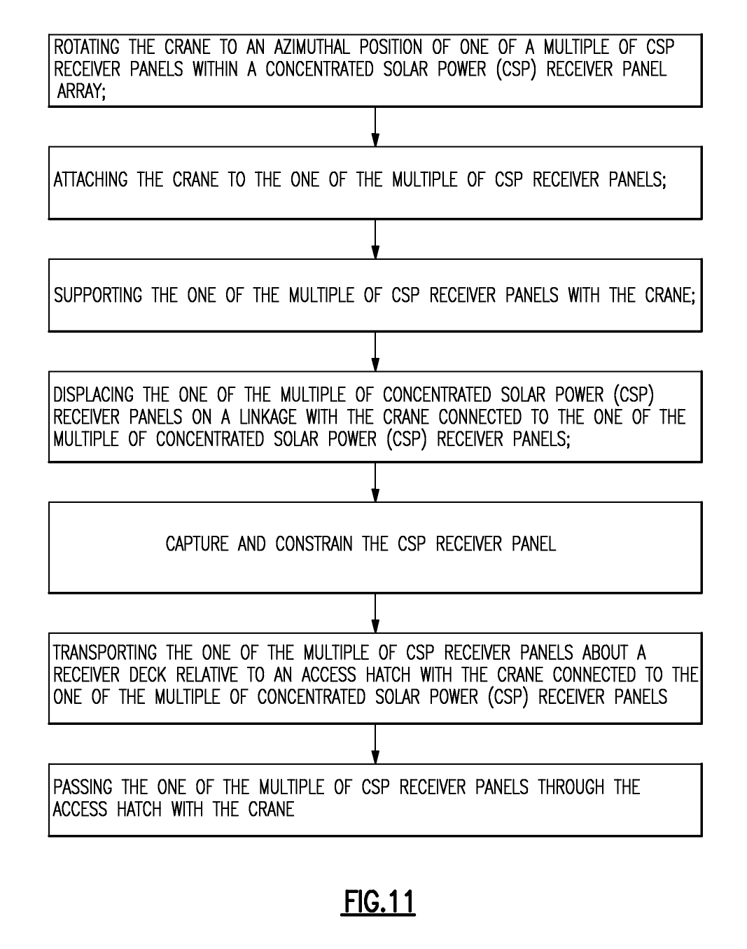

To replace a CSP receiver panel 40, the above-described operation (FIG. 11) is essentially reversed.

The physical control of the CSP receiver panel 40 throughout the repair and replacement operation reduces risk to adjacent CSP receiver panels 40 as well as reducing the risk of damage to the CSP receiver panel being moved. Moreover, the retention of physical control throughout the operations reduces risk to maintenance personnel and provides an efficient and cost effective way to move the panel with a minimum number of personnel.

It should be understood that relative positional terms such as “forward,” “aft,” “upper,” “lower,” “above,” “below,” and the like are with reference to the normal operational arrangement and should not be considered otherwise limiting.

Although particular step sequences are shown, described, and claimed, it should be understood that steps may be performed in any order, separated or combined unless otherwise indicated and will still benefit from the present disclosure.

The foregoing description is exemplary rather than defined by the limitations within. Various non-limiting embodiments are disclosed herein, however, one of ordinary skill in the art would recognize that various modifications and variations in light of the above teachings will fall within the scope of the appended claims. It is therefore to be understood that within the scope of the appended claims, the disclosure may be practiced other than as specifically described. For that reason the appended claims should be studied to determine true scope and content.

What is claimed is:

1. A solar receiver system comprising:
a tower;
a solar receiver system mounted to said tower, said solar receiver system defines an axis;
a concentrated solar power (CSP) receiver panel array having a multiple of CSP receiver panels removably mounted to said solar receiver system; and
a maintenance system mounted adjacent to said solar receiver system.

2. The system as recited in claim 1, further comprising a crane system mounted to a roof of said solar receiver system.

3. The system as recited in claim 2, wherein said crane system includes a crane body movable between a central position along said axis of said solar receiver system and an outer perimeter of said solar receiver system.

4. The system as recited in claim 3, wherein said crane system is rotatable about said axis upon a turntable such that said crane system has access to every CSP receiver panel of said concentrated solar power (CSP) receiver panel array.

5. The system as recited in claim 1, further comprising a linkage removably mounted to any one of said multiple of CSP receiver panels and said solar receiver system.

6. The system as recited in claim 5, wherein said linkage includes an upper linkage and a lower linkage.

7. The system as recited in claim 6, wherein said linkage pivots said one of said multiple of CSP receiver panels outwardly relative said axis.

8. The system as recited in claim 7, wherein said linkage pivots said one of said multiple of CSP receiver panels toward a receiver deck about said solar receiver system.

9. The system as recited in claim 1, further comprising a track defined around a receiver deck about said solar receiver system.

10. The system as recited in claim 9, further comprising:
a cart movable around said track; and
a frame assembly mounted to said cart, said frame assembly operable to selectively receive any one of said multiple of CSP receiver panels.

11. The system as recited in claim 9, further comprising:
a first cart movable around said track, said first cart supports a first frame; and
a second cart movable around said track, said second cart supports a second frame, said first frame and said second frame operable to selectively receive any one of said multiple of CSP receiver panels therebetween.

12. The system as recited in claim 11, wherein said first cart and said second cart are powered to drive around said track.

13. The system as recited in claim 11, further comprising an access hatch through said receiver deck, said access hatch sized to permit passage of any one of said multiple of CSP receiver panels.

14. The system as recited in claim 9, further comprising an access hatch through said receiver deck, said access hatch sized to permit passage of any one of said multiple of CSP receiver panels.

15. A method of replacing any one of a multiple of CSP receiver panels on a solar receiver system comprising:
displacing one of a multiple of concentrated solar power (CSP) receiver panels of a concentrated solar power (CSP) receiver panel array relative an axis of a solar receiver system on a linkage;
supporting the one of the multiple of CSP receiver panels with a crane system; and
transporting the one of the multiple of CSP receiver panels about a receiver deck about solar receiver system.

16. A method as recited in claim 15, further comprising:
moving the one of the multiple of CSP receiver panels through an access hatch within the receiver deck with the crane system.

17. A method as recited in claim 15, further comprising:
rotating the crane system to an azimuthally position of the one of the multiple of CSP receiver panels within the concentrated solar power (CSP) receiver panel array.

18. A method as recited in claim 15, wherein the displacing the one of the multiple of concentrated solar power (CSP) receiver panels occurs with a crane system connected to the one of the multiple of concentrated solar power (CSP) receiver panels.

19. A method as recited in claim 15, wherein the transporting the one of the multiple of concentrated solar power (CSP) receiver panels occurs with a crane system connected to the one of the multiple of concentrated solar power (CSP) receiver panels.

20. A maintenance system comprising:
a crane system operable to support any one of a multiple of CSP receiver panels;
a cart movable around a track, said cart operable to support said one of said multiple of CSP receiver panels for movement of said one of said multiple of CSP receiver panels while said crane is connected to said one of said multiple of CSP receiver panels.

21. The system as recited in claim 20, wherein said crane system is mounted to a roof of a solar receiver system.

22. The system as recited in claim 21, wherein said track is defined along a receiver deck about said solar receiver system.

23. An installation system comprising:
a crane supporting a load;
a frame coupled to a track, thereby forming a rigid control system;
wherein the frame is attached to the load; and
wherein a movement of the load is limited by the rigid control system.
